(19) United States
(12) Patent Application Publication
(10) Pub. No.: US 2015/0263197 A1
(43) Pub. Date: Sep. 17, 2015

(54) PHOTOVOLTAIC DEVICE INTERCONNECTION AND METHOD OF MANUFACTURING

(71) Applicant: First Solar, Inc., Perrysburg, OH (US)

(72) Inventors: Scott Jansen, Perrysburg, OH (US); Casimir P. Kotarba, Perrysburg, OH (US); Jonathan Pappas, Perrysburg, OH (US); Rick Powell, Perrysburg, OH (US); Yann Roussillon, Perrysburg, OH (US); Erica Van Nortwick, Perrysburg, OH (US); Charles Wickersham, Perrysburg, OH (US)

(21) Appl. No.: 14/657,350

(22) Filed: Mar. 13, 2015

Related U.S. Application Data
(60) Provisional application No. 61/953,279, filed on Mar. 14, 2014.

(51) Int. Cl. H01L 31/0224; H01L 31/18; H01L 51/44

(52) U.S. Cl. CPC H01L 31/022441; H01L 51/441; H01L 31/188; H01L 31/1884

(57) ABSTRACT

A photovoltaic device includes a substrate and has a transparent conductive oxide layer, a conductive back layer, and at least one intermediate semiconductor layer formed thereon. An isolation scribe divides and electrically isolates the oxide layer, the back layer and the semiconductor layer to define two photovoltaic cells. A conductor extends across the isolation scribe and connects the back layer of one photovoltaic cell to the oxide layer of the other photovoltaic cell.

### CROSS-REFERENCE TO RELATED APPLICATION

This application claims the benefit of priority of U.S. Provisional Patent Application Ser. No. 61/953,279 filed on Mar. 14, 2014 hereby incorporated herein by reference in its entirety.

### BACKGROUND OF THE INVENTION

This invention relates in general to a photovoltaic device (or photovoltaic device). Thin film photovoltaic devices are formed by the deposition of multiple semiconductor or organic thin films on rigid or flexible substrates or superstrates. Electrical contact to the solar cell material on the substrate side is provided by an electrically conductive substrate material or an additional electrically conductive layer between the solar cell material and the substrate such as a transparent conductive layer.

Photovoltaic devices typically comprise subdevices connected in parallel. Each subdevice comprises multiple photovoltaic cells, typically connected in series. The photovoltaic devices are typically split into subdevices and cells by a plurality of scribe lines often referred to as a P1 scribe, a P2 scribe, and a P3 scribe. The P1 scribe provides electrical isolation between the cells by isolating a front contact layer (often referred to as a TCO layer), the P2 scribe immediately adjacent the P1 scribe provides interconnection of the cells and involves removal of all layers of the device down to the front contact layer to facilitate electrical connection with the front contact layer via a conductive coating, and the P3 scribe adjacent to the P2 scribe and is another isolation scribe that ablates through and isolates the metal back contact layer of each cell. Areas of the subdevices may be less efficient or may not be electrically conductive at all due to the scribes and the areas of the device lost due to scribing. Areas of the cells located between P1 and P3 are not functional, i.e., non-electrically conductive, thus lowering an electrical output of each cell of the device. The non-electrically conductive area(s) are typically the width of the P1 scribe plus the space between the P1 and P2 scribes plus the width of the P2 scribe plus the spacing between the P2 and P3 scribes plus the width of the P3 scribe (i.e., P1 width+P2/P3 spacing+P2 width+P2/P3 spacing+P3 width), as best shown in FIG. 12. Thus, it would be desirable to minimize non-electrically conductive areas photovoltaic devices and, in general, to develop a more efficient photovoltaic device.

### SUMMARY OF THE INVENTION

Concordant and congruous with the present invention, a more efficient photovoltaic device has surprisingly been discovered.

In one embodiment of the invention, a photovoltaic device comprises a substrate having a transparent conductive oxide layer, a conductive back contact layer, and a semiconductor layer formed thereon; an isolation scribe formed through the transparent conductive oxide layer, the conductive back contact layer, and the semiconductor layer to define a first photovoltaic cell and a second photovoltaic cell, the isolation scribe electrically isolating the first photovoltaic cell from the second photovoltaic cell; and an interconnection scribe formed through the back contact layer and the semiconductor layer of the second photovoltaic cell, the interconnection scribe spaced laterally apart from the isolation scribe and facilitating a series connection between the first photovoltaic cell and the second photovoltaic cell.

In another embodiment of the invention, a method for manufacturing a photovoltaic device comprises forming a plurality of isolation scribes in a photovoltaic device through a transparent conductive oxide layer, a semiconductor layer, and a back contact layer of disposed upon a substrate to define an array of photovoltaic cells on the photovoltaic device; forming interconnection scribes through the semiconductor layer and the back contact layer of each of the photovoltaic cells to expose a portion of the transparent conductive oxide layer; and depositing a dielectric material into the plurality of isolation scribes, wherein at least a portion of the dielectric material is disposed on at least a portion of the back contact layer of one of the photovoltaic cells, a portion of the back contact layer of a another of the photovoltaic cells adjacent to the one of the photovoltaic cells, and at least a portion of the interconnection scribe of the one of the photovoltaic cells.

### BRIEF DESCRIPTION OF THE DRAWINGS

FIG. 1 is a perspective view of a photovoltaic device.

FIG. 2 is a schematic, side view taken along the cut line 2-2 of FIG. 1, showing a photovoltaic cell according to an embodiment of the invention.

FIG. 2a is a schematic, side view of a photovoltaic cell according to another embodiment of the invention.

FIG. 3 is a schematic, side view taken along the cut line 3-3 of FIG. 1, showing a photovoltaic cell including a bus bar.

FIG. 4 is a schematic, side view taken along the cut line 4-4 of FIG. 1, showing a photovoltaic cell including a second bus bar.

FIG. 5 is a flow chart of one method to manufacture the photovoltaic device shown in FIG. 1.

FIG. 6a is a perspective view of a portion of the photovoltaic device before any scribes have been cut.

FIG. 6b is a schematic, side view of the photovoltaic device shown in FIG. 6a.

FIG. 7a is a perspective view of a portion of the photovoltaic device shown in FIG. 6a after isolation scribes have been cut.

FIG. 7b is a schematic, side view of the photovoltaic device shown in FIG. 7a.

FIG. 8a is a perspective view of a portion of the photovoltaic device shown in FIG. 7a after interconnection scribes have been cut in the photovoltaic device.

FIG. 8b is a schematic, side view of the photovoltaic device shown in FIG. 8a.

FIG. 9a is a perspective view of a portion of the photovoltaic device shown in FIG. 8a after a dielectric material has been added to cover portions of the photovoltaic device.

FIG. 9b is a schematic, side view of the photovoltaic device shown in FIG. 9a.

FIG. 10a is a perspective view of a portion of the photovoltaic device shown in FIG. 9a after portions of the dielectric material have been removed.

FIG. 10b is a schematic, side view of the photovoltaic device shown in FIG. 10a.

FIG. 11a is a perspective view of a portion of the photovoltaic device shown in FIG. 10a after a metallic interconnection material has been added to portions of the photovoltaic device.

FIG. 11b is a schematic, side view of the photovoltaic device shown in FIG. 11a.

FIG. 12 is a schematic, side view of a photovoltaic device as known in the art.

FIG. 13 is a flow chart of another method to manufacture a photovoltaic device (shown in FIGS. 14a and 14b) according to another embodiment of the invention.

FIG. 14a is a schematic, side view of the photovoltaic device manufactured by the method of FIG. 13 during an ablation step.

FIG. 14b is a schematic, side view of the photovoltaic device of FIG. 14a after the ablation step and during a curing step.

### DETAILED DESCRIPTION OF THE PREFERRED EMBODIMENT

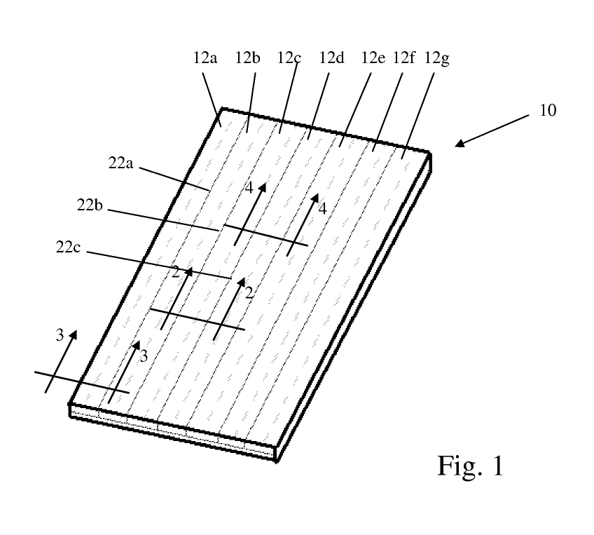

Referring now to the drawings, there is illustrated in FIG. 1 a perspective view of a photovoltaic device, indicated generally at 10. The photovoltaic device 10 includes a plurality of photovoltaic cells, 12a, 12b, 12c, etc. The illustrated photovoltaic cells 12a, 12b, 12c, etc. are not shown to scale, and are provided for purposes of explanation of the features of the photovoltaic device 10. The photovoltaic device 10 may have a different number of photovoltaic cells from that illustrated. Each photovoltaic cell is electrically connected to at least one adjacent photovoltaic cell, as will be described below. Furthermore as will be described herein, each cell of the device 10 will include one or more layers of material. Each layer can cover all or a portion of the device 10 and/or all or a portion of a layer or a substrate underlying the layer. For example, a “layer” can include any amount of any material that contacts all or a portion of a surface. Furthermore, layers herein may be described generally by a numeral (e.g., 18) or individually for a particular cell by a numeral and a character (e.g., 18c). It is understood that disclosure with respect to a particular layer for a particular cell may apply in similar fashion to layers of other cells or of the layer generally, except where noted otherwise.

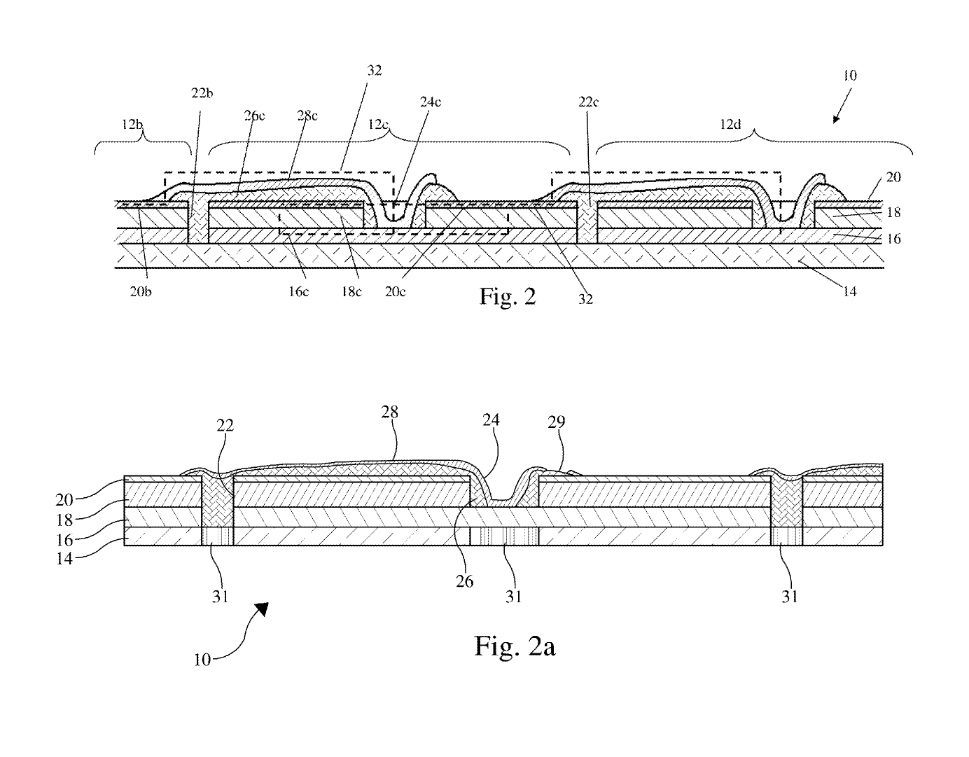

Referring to FIG. 2, a side view of a portion of the photovoltaic device 10, taken along the cut line 2-2 of FIG. 1 is shown. The photovoltaic device 10 includes a transparent substrate 14. The transparent substrate 14 is formed of a material that provides rigid support, light transmission, chemical stability and typically includes one of a float glass, soda lime glass, polymer, or other suitable material. The photovoltaic device 10 includes a transparent conductive oxide (TCO) layer 16. The transparent conductive oxide layer 16 is formed of a material that provides low resistance electrical conduction, chemical and dimensional stability and typically includes one of a tin oxide, zinc oxide, cadmium stannate, combinations or doped variations thereof, or any other suitable material. The photovoltaic device 10 includes a semiconductor layer 18. The semiconductor layer 18 is formed of a photoactive material or combination of materials. Typically, the semiconductor layer includes one or more n-type or p-type semiconductors to form a p-n junction. In one embodiment, the semiconductor layer 18 is a semiconductor bi-layer including an n-type cadmium sulfide and a p-type cadmium telluride, however other compounds and materials may be used, including silicon based semiconductors, copper indium gallium selenide, and other suitable materials. The photovoltaic device 10 includes a back contact layer 20. The back contact layer 20 is an electrically conductive material, typically selected from among silver, nickel, copper, aluminum, titanium, palladium, chromium, molybdenum, gold, and combinations thereof.

As previously described in reference to FIG. 1, the photovoltaic device 10 is divided into a plurality of photovoltaic cells 12a, 12b, 12c, etc. Adjacent photovoltaic cells are separated by isolation scribes 22a, 22b, 22c, etc., which electrically isolate each photovoltaic cell from the one or more adjacent photovoltaic cells. For example, in reference to FIG. 2, the photovoltaic cell 12c is isolated from the photovoltaic cell 12b by the isolation scribe 22b, and is isolated from the photovoltaic cell 12d by the isolation scribe 22c. The isolation scribes 22a, 22b, 22c, etc. divide the several layers of the photovoltaic device into separate cells, and so the photovoltaic cell 12c includes a cell transparent conductive oxide layer 16c, a cell semiconductor layer 18c, and a cell back contact layer 20c. These layers are isolated from the similar layers of adjacent photovoltaic cells 12b and 12d by the isolations scribes 22b and 22c.

The photovoltaic cell 12c includes an interconnection scribe 24c spaced laterally apart from the isolation scribe 22c. Instead of the interconnection scribe 24c being located at an end or an edge of a cell 12c adjacent the isolation scribe 22c, the interconnection scribe 24c is located at or near a center of the cell 12c. The interconnection scribe 24c provides an opening through at least a portion of the back contact layer 20 and the semiconductor layer 18 and provides access to the TCO layer 16c. A dielectric material 26c is disposed within the isolation scribe 22b. The dielectric material 26c may be a UV curable polymer, for example, or any suitable electrically insulating material as desired. The dielectric material 26c also covers a portion of the back contact layer 20b of the photovoltaic cell 12b, a portion of the back contact layer 20c of the photovoltaic cell 12c, and a portion of the interconnection scribe 24c of the photovoltaic cell 12c. Similar to the device 10 shown in FIG. 2a, the isolation scribe 22c and the interconnection scribe 24c are spaced apart such that the only non-electrically conductive area corresponding to the non-electrically conductive area 31 of FIG. 2a is a width of the isolation scribe 22c (the P1 scribe) plus the width of the interconnection scribe 24c (the P2 scribe) (or P1 width+P2 width), thereby resulting in a device 10 having a larger active area able to generate additional electricity as compared to prior art devices. By forming the interconnection scribe 24c spaced apart from the isolation scribe 22c, resistance loses of current traveling through the TCO layer 16c is minimized. If resistances in the TCO layer 16c are minimized, TCO layers 16c may be formed from materials with higher resistances but with an increase in transmission (e.g., higher Isc).

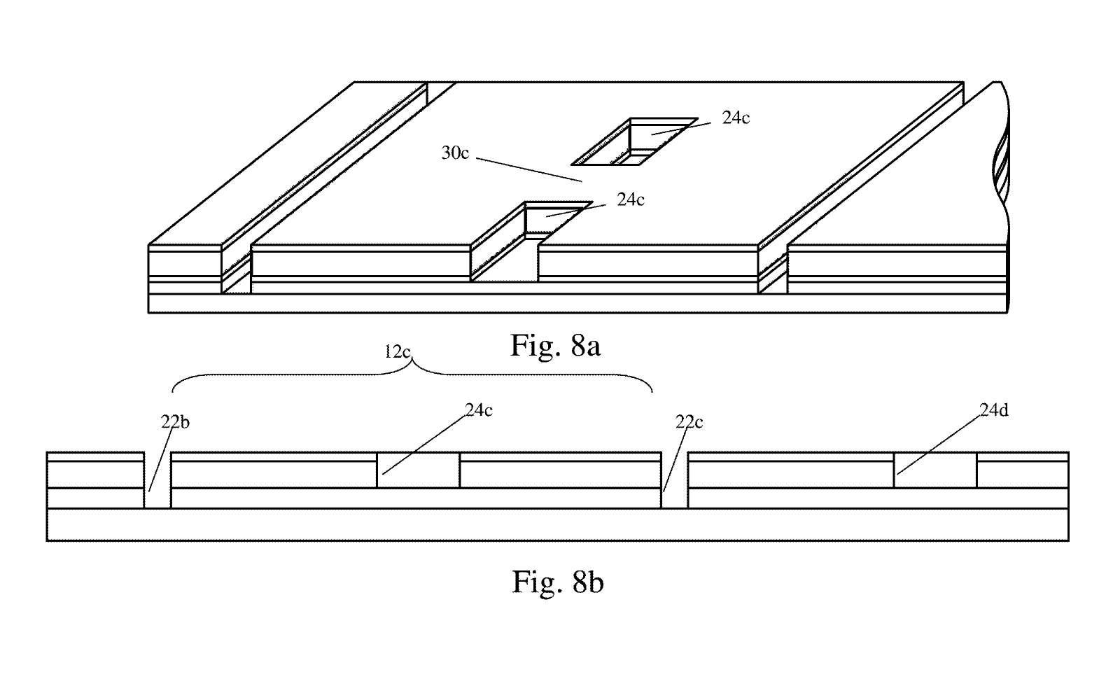

The photovoltaic device 10 includes a metallic interconnection material 28c that is disposed in electrical contact with a portion of the transparent conductive oxide material 16c of the photovoltaic cell 12c, and in electrical contact with a portion of the back contact layer 20b of the adjacent photovoltaic cell 12b. The metallic interconnection material 28 may include titanium, aluminum, nickel, chromium, tantalum, copper, tungsten, titanium nitride, tantalum nitride, tungsten nitride and various compounds and combinations thereof. One example embodiment of photovoltaic cell 12 may include a back contact layer 20 comprising a compound of molybdenum, nickel, aluminum and a metallic interconnection layer 28 comprising a compound of titanium and aluminum. Alternatively, a second exemplary embodiment may include a back contact layer 20 comprising a compound of molybdenum, nickel, aluminum, and chromium, and a metallic interconnection layer 28 comprising a compound of tungsten and copper. This forms a series connection between the photovoltaic cell 12c and the adjacent photovoltaic cell 12b. As shown in FIG. 8a, the interconnection scribe 24c is a series of discrete scribes that are separated by non-scribed space 30c. Therefore, the back contact layer 20c of the photovoltaic cell 12c extends from a first side of the interconnection scribe 24c to a second side of the interconnection scribe 24c and provides a conductive pathway across the full width of the photovoltaic cell 12c. Referring back to FIG. 2, an electrical current flow path is shown by the dashed line 32.

Although photovoltaic cell 12c and its connection to adjacent photovoltaic cell 12b has been described in detail, it should be appreciated that all the photovoltaic cells in the photovoltaic device 10 may be similarly connected to the adjacent photovoltaic cells. The other photovoltaic cells will not be described in detail, with the exception of a photovoltaic cell 12h and a photovoltaic cell 12i.

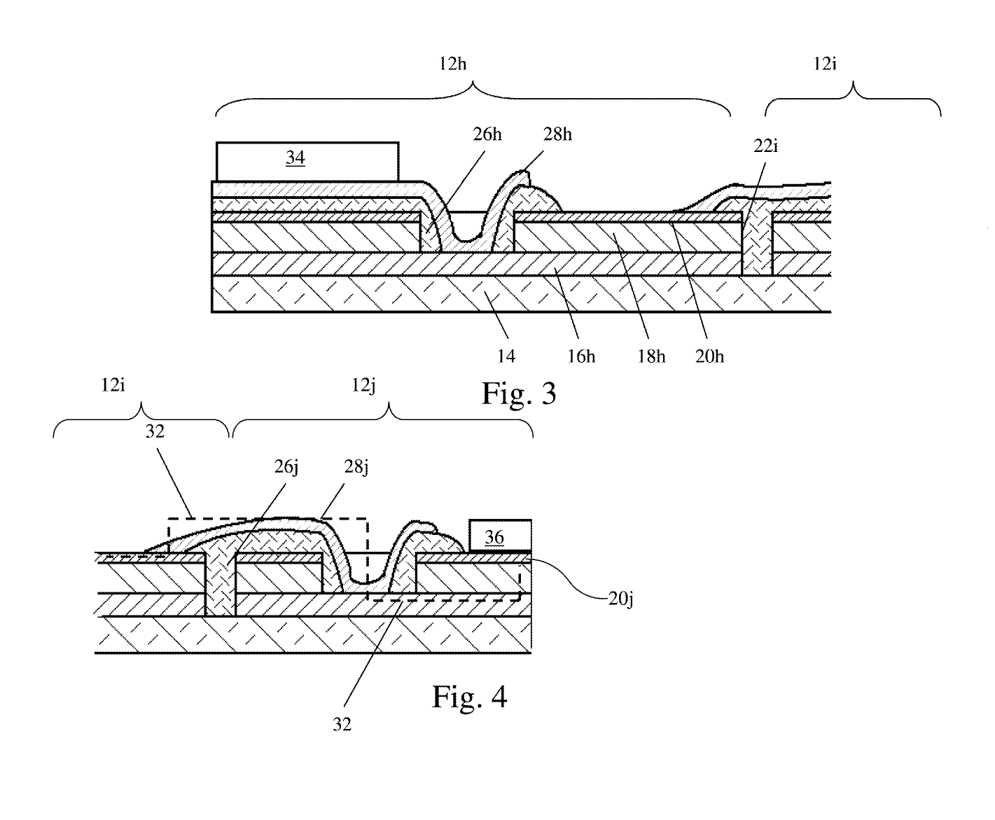

Referring to FIG. 3, side, schematic view of the photovoltaic cell 12h is shown. The photovoltaic cell 12h includes many features similar to the previously described photovoltaic cell 12c, and similar features are identified with similar numbers with the suffix letter “h.” The photovoltaic cell 12h includes a bus bar 34 that is in electrical contact with a front contact layer 16h. The configuration of the photovoltaic cell 12h is such that the space below the bus bar 34 is photovoltaicly active, and is not dead space. The bus bar 34, along with other bus bars in the device, provide electrically accessible features within the photovoltaic device to engage with other integration components (not shown), including conductive tapes and foils which may pass through an edge encapsulant, back cover glass or other device enclosure to facilitate the interconnection of multiple devices, the connection of the device to an electrical load, grid, array, or otherwise.

Referring to FIG. 4, a side, schematic view of the photovoltaic cell 12j is shown. The photovoltaic cell 12j includes many features similar to the previously described photovoltaic cell 12c, and similar features are identified with similar numbers with the suffix letter “j.” The photovoltaic cell 12j includes a bus bar 36 that is in electrical contact with a back contact layer 20j. The configuration of the photovoltaic cell 12j is such that the space below the bus bar 36 is photovoltaicly active, and is not dead space. The bus bar 36 creates an electrical circuit with the bus bar 34 in the photovoltaic cell 12h.

It should be appreciated that the photovoltaic device may include the bus bar 34 at one end, and the bus bar 36 at the opposite end, placing all the photovoltaic cells in the photovoltaic device in series. Alternatively, the photovoltaic device may include to matching bus bars similar to one of bus bar 34 and bus bar 36 at each end of the photovoltaic device, and a single bus bar similar to the other of bus bar 36 and bus bar 34 in the center of the photovoltaic device. In that case, the photovoltaic device would include two subdevices, and the center bus bar would be connected to two series of photovoltaic cells, extending to each edge of the photovoltaic device. It should be appreciated that the center bus bar would include a mirror image, taken through the center line of the bus bar, of the configuration shown in one of FIG. 3 and FIG. 4. Additionally, it should be appreciated that the photovoltaic device may be divided into more than two subdevices, if desired, with the appropriate number and placement of bus bars.

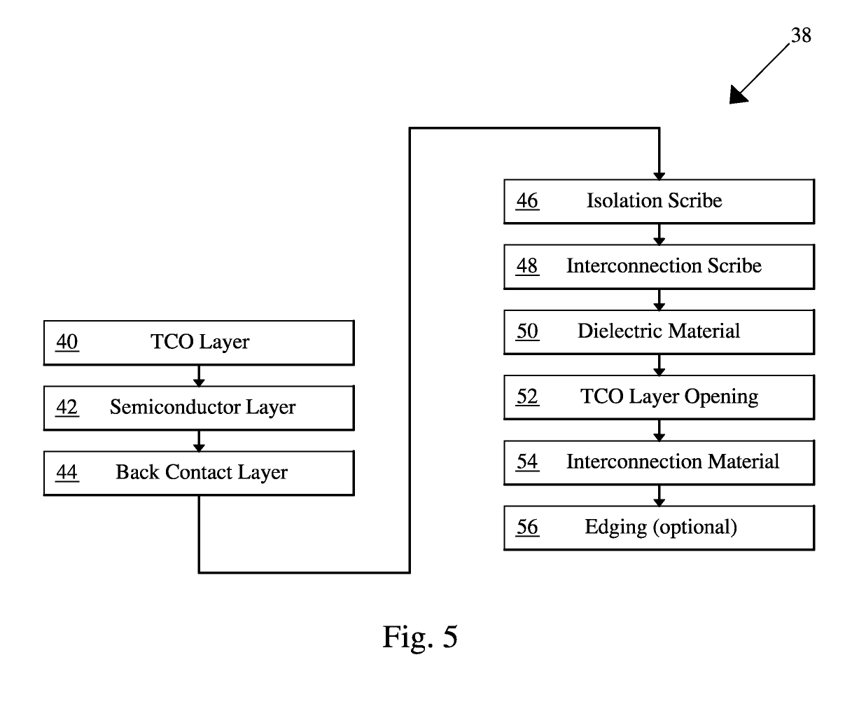

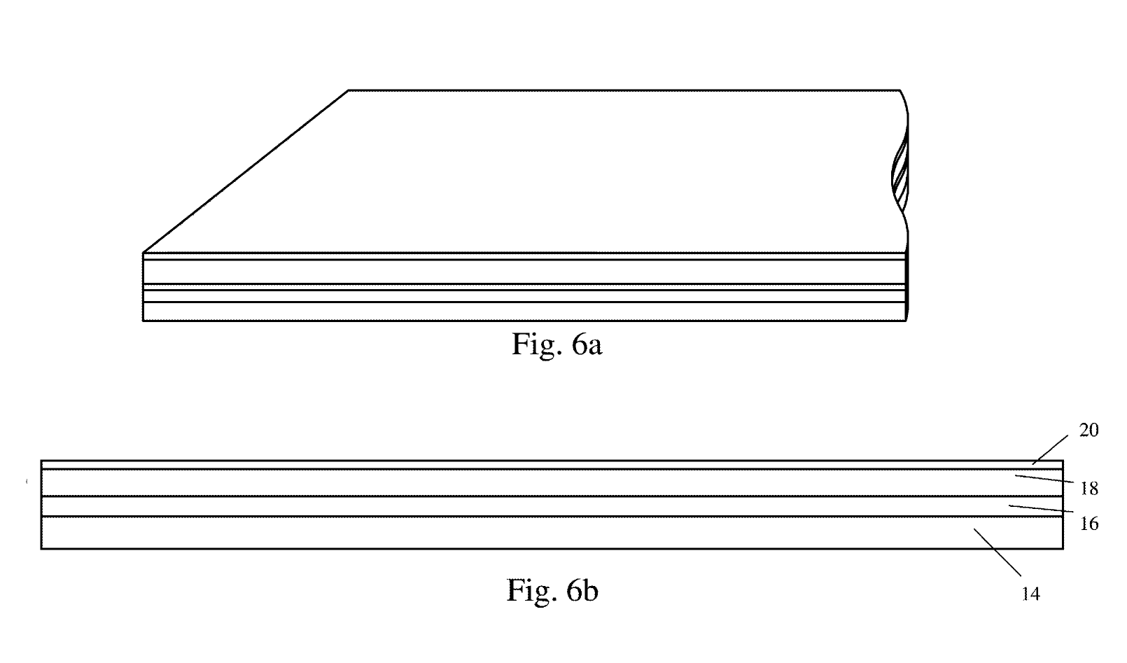

Referring now to FIG. 5, a flow chart of a method for manufacturing the photovoltaic device 10 is shown generally at 38. The steps of the method shown in FIG. 5 are best understood in further reference to FIGS. 6a and 6b through 11a and 11b.

Step 40 is the application of the transparent conductive oxide layer 16 to the transparent substrate 14. Processes to apply the transparent conductive oxide layer 16 to the transparent substrate 14 are known in the art, and will not be detailed here. The transparent conductive oxide layer 16 is applied across the full surface of the transparent substrate 14. Step 42 is the application of the semiconductor layer 18. Processes to apply the semiconductor layer 18 are known in the art, and will not be detailed here. The semiconductor layer 18 is applied across the full surface of the transparent conductive oxide layer 16. Step 44 is the application of the back contact layer 20. Processes to apply the back contact layer 20 are known in the art, and will not be detailed here. The back contact layer 20 is applied across the full surface of the semiconductor layer 18. The back contact layer 20 may be sealed with, for example, chromium. At this point, the photovoltaic device 10 is in the condition shown in FIGS. 6a and 6b. It should be appreciated that the back contact layer 20, by covering the full surface of the semiconductor layer 18, provides protection against undesirable oxidation, contamination or deterioration of the semiconductor layer 18. As a result, the photovoltaic device may be brought through step 44, and then moved to a different facility where additional steps may be performed, without degradation of the materials of photovoltaic device.

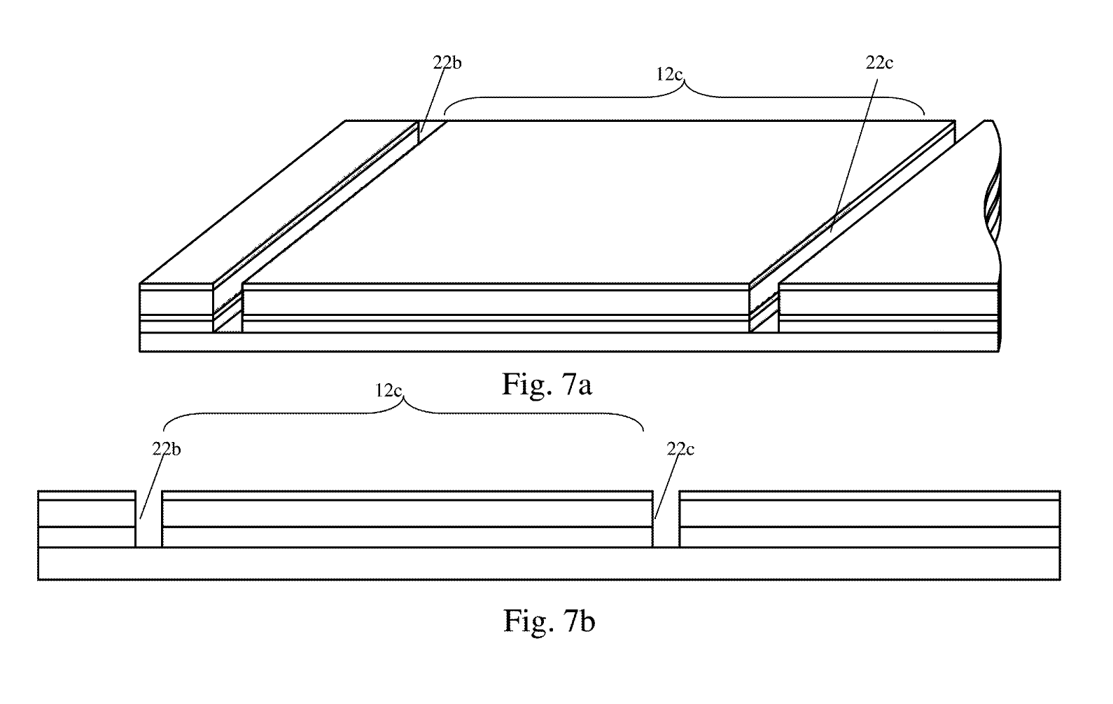

At step 46 the isolation scribes 22a, 22b, 22c, etc. are cut into the photovoltaic device 10. The disposition of the photovoltaic device 10 after step 46 is shown in FIGS. 7a and 7b. The isolation scribes 22a, 22b, 22c, etc. are cut using a laser that ablates the transparent conductive oxide layer 16, the semiconductor layer 18, and the back contact layer 20 without affecting and/or altering the transparent substrate 14.

At step 48 interconnection scribes 24a, 24b, 24c, etc. are cut into the photovoltaic device 10. The disposition of the photovoltaic device 10 after step 48 is shown in FIGS. 8a and 8b. The interconnection scribes 24a, 24b, 24c, etc. are cut using a laser that ablates the semiconductor layer 18 and the back contact layer 20 without affecting and/or altering the transparent substrate 14 and the transparent conductive oxide layer 16. The interconnection scribes 24a, 24b, 24c, etc. may comprise a series of discontinuous ablations of material between two isolation scribes (as shown in FIG. 8a), for example isolation scribes 22a and 22b, or alternatively, between an isolation scribe and an end edge of the photovoltaic device, for example isolation scribe 22a. The discontinuous ablations of the interconnection scribes 24a, 24b, 24c, etc. may result in a series of substantially circular dots or short rectilinear scribes (not shown) or the discontinuous ablation may result in a dashed line scribe, as best shown in FIG. 8a. Alternatively, the interconnection scribes 24a, 24b, 24c, etc. may comprise a continuous ablation of material resulting in an elongate trough.

Regardless of the shape and/or length of the interconnection scribes 24a, 24b, 24c, etc. and as best shown in FIG. 2, the photovoltaic device 10 does not include a so-called P3 scribe as is known in the art. Instead, the device 10 includes the isolation scribe 22 (a P1 scribe) and the interconnection scribe 24 (a P2 scribe) spaced apart from another isolation scribe(s) 22 (another P1 scribe). The P3 scribe is replaced by an additional metallic interconnection material 28 discussed hereinafter in more detail. By eliminating a P3 scribe as known in the art, the isolation scribe 22 (the P1 scribe) and the interconnection scribe 24 (the P2 scribe) may be performed by the same laser-providing device, thereby minimizing a cost of equipment for producing the device 10 and the space required to manufacture the device 10. Furthermore, by eliminating the P3 scribe known in the art, scribe tolerances of the isolation scribe 22 (the P1 scribe) and the interconnection scribe 24 (the P2 scribe) may be relaxed. That is, because there is no second isolation scribe (the P3 scribe) spacing considerations or constraints between the isolation scribe 22 (the P1 scribe) and the P3 isolation scribe are eliminated and the accuracy of the interconnection scribe 24 (the P2 scribe) may be relaxed from, for example, by about +/−20 μm to about +/−100 μm, thereby allowing for less stringent process controls.

Another embodiment of photovoltaic device 10 of the invention is shown in FIG. 2a. The embodiment of FIG. 2a is substantially similar to the embodiment of FIG. 2 except that the metallic interconnection material 28 includes an etch 29 that is an isolation etch that, unlike the P3 scribe, only removes a portion of the metallic interconnection material 28 and does not etch or ablate the back contact layer 20. The etch 29 may be formed by a wet or dry etch as known in the art, or a laser may be used to ablate the material 28 to form the etch 29, as desired. The etch 29 is formed in the metallic interconnection material 28 thus negating the need for a P3 scribe, thereby militating against the unintentional removal or affecting of the back contact layer 20.

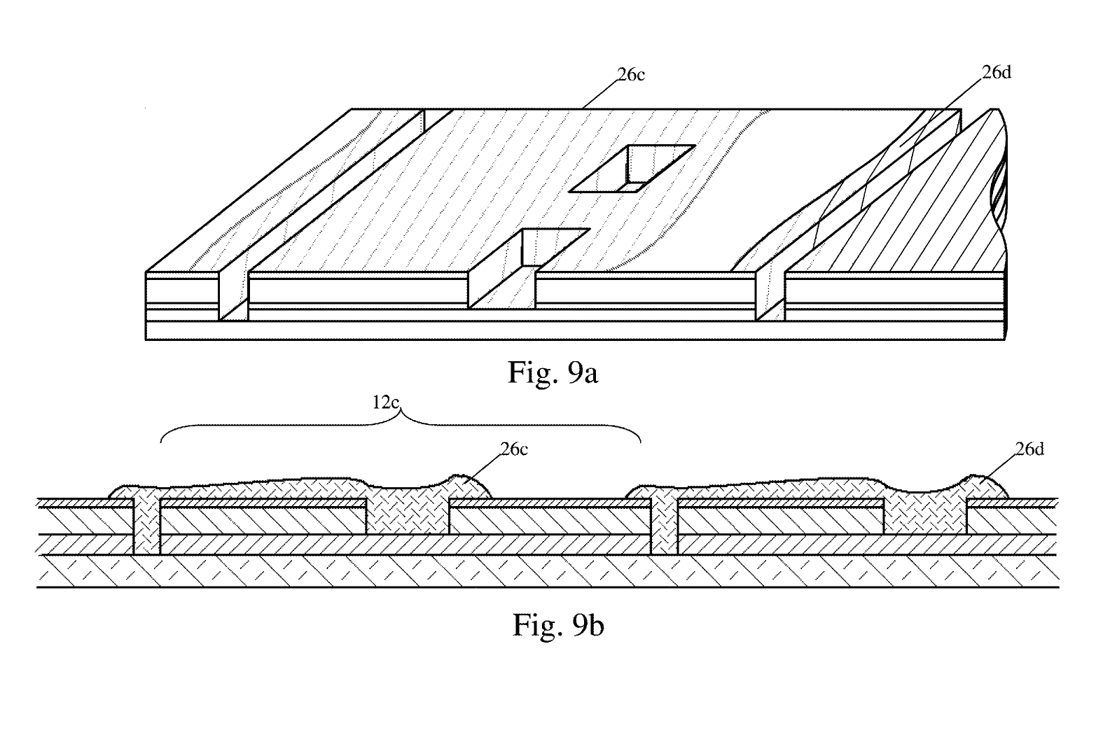

In one embodiment of the invention, at step 50 dielectric material 26a, 26b, 26c, etc. is deposited on the photovoltaic device 10. The disposition of the photovoltaic device 10 after step 50 is shown in FIGS. 9a and 9b. The dielectric material 26a, 26b, 26c, etc. is applied using an inkjet printing process, though any other desired process suitable to apply the dielectric material 26a, 26b, 26c, etc. may be used, such as a roll coating process, spraying application, and the like.

According to an embodiment of the invention, the step 50 involves selectively depositing the dielectric material 26a, 26b, 26c, etc. whereby the dielectric material 26a, 26b, 26c, etc. includes at least two portions. The first portion of the dielectric material 26a, 26b, 26c, etc. has a thickness, and the first portion is deposited on at least a portion of the device 10 where the dielectric material 26a, 26b, 26c, etc. will not be ablated. The second portion of the dielectric material 26a, 26b, 26c, etc. has a thickness less than that of the first portion. The second portion of the dielectric material 26a, 26b, 26c, etc. is deposited on a portion of the device 10 that is to be ablated. The second portion of the dielectric material 26a, 26b, 26c, etc. that is to be ablated may be deposited in the interconnection scribe 24, for example, though the second portion may be deposited on other areas of the device 10 to be ablated, as desired.

The process of selectively depositing the dielectric material 26a, 26b, 26c, etc. having the first portion and the second portion is conducted using a single-pass inkjet printing process (or other single-pass deposition process) such that the first portion of the dielectric material 26a, 26b, 26c, etc. is deposited to provide insulation between metal layers of the device 10, such as between the back contact layer 20 and the metallic interconnection material 28, for example, and the second portion of the dielectric material 26a, 26b, 26c, etc. is deposited over areas to be ablated. Because the second portion has a thickness less than the thickness of the first portion, the second portion of the dielectric material 26a, 26b, 26c, etc. is more easily ablated and removed, thereby minimizing waste and facilitating thorough and efficient ablation thereof. The single-pass process of depositing the dielectric material 26a, 26b, 26c, etc. may be performed using an inkjet process with printhead control by reducing a voltage of center aligned piezoelectric (PZ) jets of the inkjet printer. Alternatively, the portions of the dielectric material 26a, 26b, 26c, etc. thicknesses may be controlled by altering: the voltage charge (e.g., altering the waveform associated with each jet) to increase or decrease a volume of material discharged thereby; the number of attenuated jets; and a time between the deposition of the first portion and a curing step and the deposition of the second portion and a curing step (e.g., allowing more time between deposition and cure facilitates the spreading of the material over a larger area).

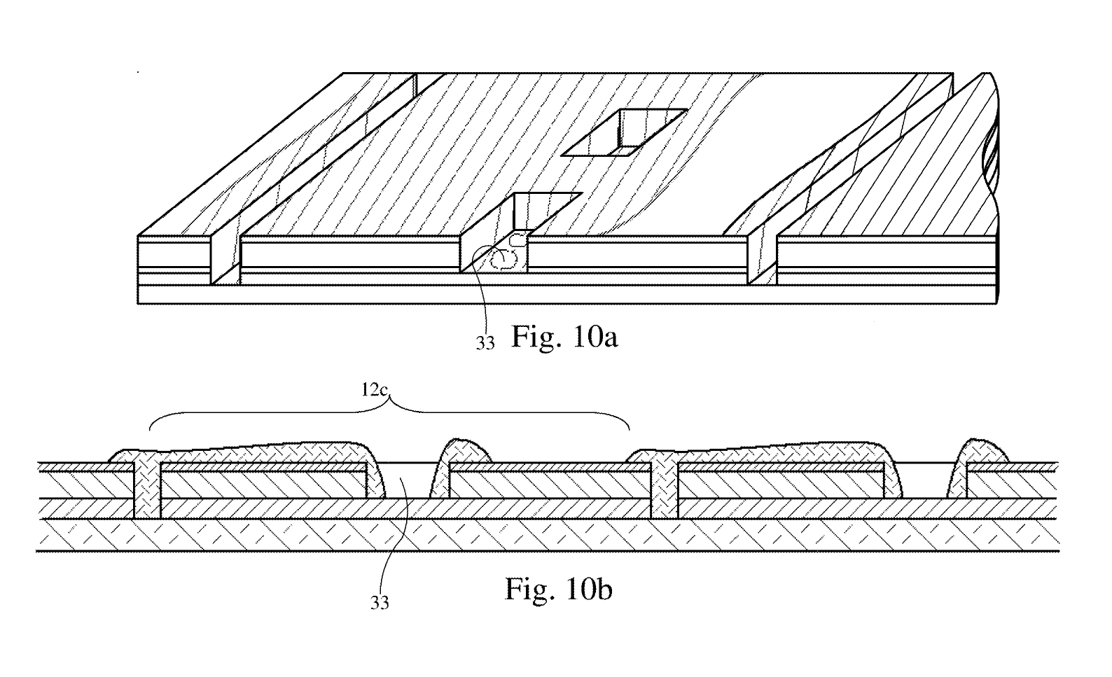

In yet another embodiment of the invention, the step 50 involves selectively depositing the dielectric material 26a, 26b, 26c, etc. to form gaps (also known as vias) 33 (as shown in FIGS. 10a and 10b) in the dielectric material 26a, 26b, 26c, etc. The gaps 33 may be metallized in a step 54 (as described below in more detail) to form contacts between conductive surfaces of the device 10. The size and shape of the gaps 33 may be controlled by altering one or more of the following: PZ inkjet deposition conditions, such as a temperature of the dielectric material ink (i.e., higher temperature inks will have a different viscosity and surface tension compared to inks having a lower temperature); a temperature of the substrate 14; by controlling surface conditions of the substrate 14 and a contact wetting angle by treatment of the surface of the substrate 14 such as mild acid etch, oxidizing chemical treatments, plasma or corona ionization of the surface (e.g., a TCO layer), or interfacial chemical adsorption; and a length of time between deposition of the dielectric material 26a, 26b, 26c, etc. and a curing thereof (as noted herein).

Using an inkjet printing process, the gaps 33 are formed by providing an image programmed into the inkjet printer to be converted to an appropriate inkjet waveform to enable ink droplet size control and to position the match of the image. The images may result in a substantially identical printed ink or the image biasing may be used to obtain a printed ink having a different but desired shape. Furthermore, the substrate 14 may be modified so that a surface thereof is unfavorable for ink wetting. For example, a two-printhead printer system may be used where a first printhead applies an inverse pattern to a desired pattern resulting in the gaps 33, the inverse pattern applied with a material that causes the ink to dewet. The second printhead then deposits either a blanket coating of material or a selective coating of material, and the dewetting material is then removed using a selective chemical etch, heating, or a plasma treatment.

The gaps 33 formed by the process according to this embodiment of the invention would be similar to those shown in FIGS. 10a and 10b. According to this embodiment of the invention, the following step 52 is not required to be performed to ablate the dielectric material 26a, 26b, 26c, etc. in contact with the transparent conductive oxide layer 16 within the interconnection scribe 24a, 24b, 24c, etc. Because the step 52 is not required to be performed, contact between the laser for the ablation of the step 52 and the TCO layer 16 is eliminated, thereby mitigating against unintentional removal of or undesirable effects on the TCO layer 16.

In yet another embodiment of the invention where the dielectric material 26a, 26b, 26c, etc. is a curable material, such as a UV curable polymer, the step 50 involves application of the curable material and a two-step curing procedure. The curable material has a viscosity low enough that the curable material may flow upon application to smooth out striations from the depositing step. In this embodiment, the step 50 includes a step of partially curing the dielectric material 26a, 26b, 26c, etc. to allow the curable material to retain a desired shape, such as a shape formed by a laser-patterning step or ablation step without fully curing the curable material. The material removal of step 52 (described in further detail below) is then performed on the curable material forming the dielectric material 26a, 26b, 26c, etc. to remove at least a portion thereof and to give the dielectric material 26a, 26b, 26c, etc. a desired shape. The dielectric material 26a, 26b, 26c, etc. is then fully cured, thereby resulting in the dielectric material 26a, 26b, 26c, etc. retaining the desired shape formed by the removal step 52. By providing a flowable and formable curable material as the dielectric material 26a, 26b, 26c, etc. that is cured in multiple steps and has a desired shape, the cross-sectional profile of the dielectric material 26a, 26b, 26c, etc. is compatible with a deposition of a metallic material as described in the step 54, thereby minimizing undesirable effects of laser ablation such as shunting, or undesirably high resistances.

At step 52 at least a portion of the dielectric material 26a, 26b, 26c, etc. in contact with the transparent conductive oxide layer 16 within the interconnection scribe 24a, 24b, 24c, etc. is removed to form the gaps 33. The disposition of the photovoltaic device 10 after step 52 is shown in FIGS. 10a and 10b. The dielectric material 26a, 26b, 26c, etc. is removed using a laser that ablates the dielectric material 26a, 26b, 26c, etc. without affecting and/or altering the transparent substrate 14 and/or the transparent conductive oxide layer 16. As noted above, step 52 is not performed in the embodiment of the invention where the dielectric material 26a, 26b, 26c, etc. is deposited and the depositing process forms the gaps 33.

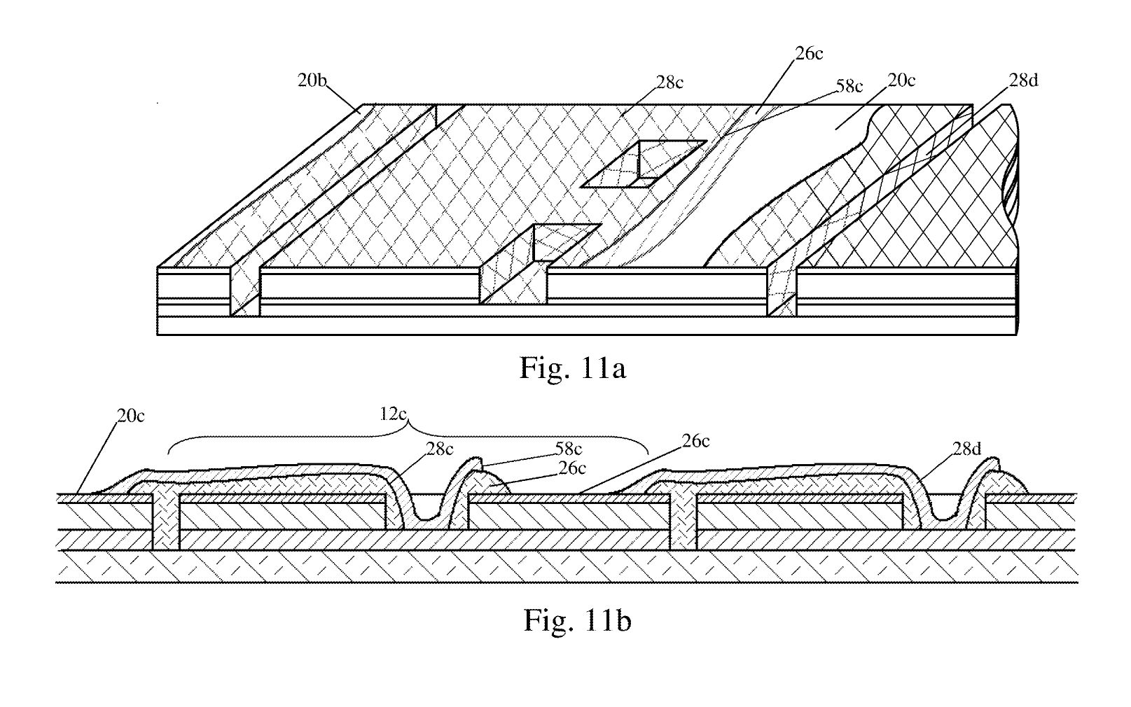

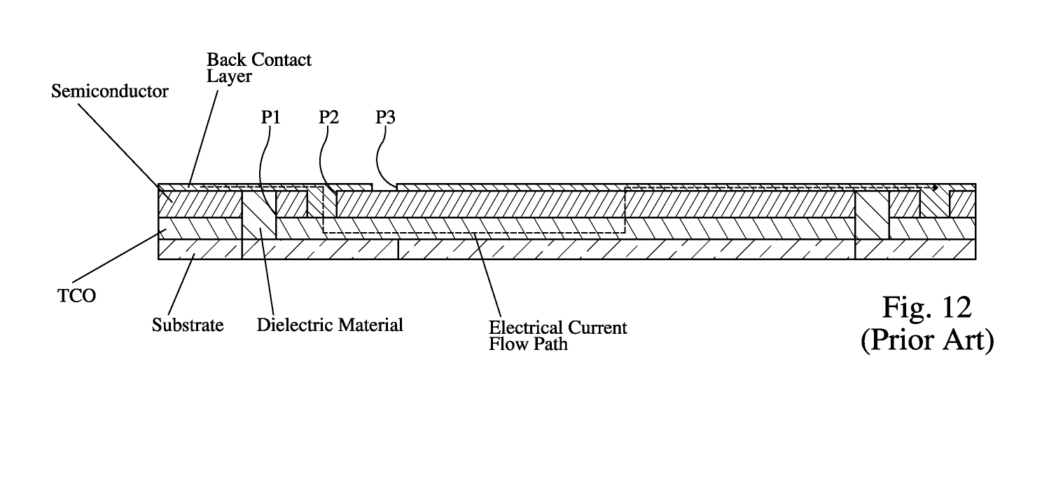

At step 54, metallic interconnection material 28a, 28b, 28c, etc. is applied to the photovoltaic device. The disposition of the photovoltaic device 10 after step 54 is shown in FIGS. 11a and 11b. The metallic interconnection material 28a, 28b, 28c, etc. is applied using an inkjet printing process, though any other desired process suitable to apply the material may be used. The metallic interconnection material 28a, 28b, 28e, etc., may be deposited over the entirety of the photovoltaic device's exposed surface, or alternatively may be selectively deposited within certain regions and not others. For example, as shown in FIGS. 11a and 11b, the metallic interconnection material 28a, 28b, 28c, etc. may be selectively deposited to overlap slightly onto the back contact layer 20a, 20b, 20c, etc. of the photovoltaic cell adjacent to photovoltaic cell 12c and continuously over dielectric material 26c to the interconnection scribe 24c.

At optional step 56, an edge 58a, 58b, 58c, etc. is created on the metallic interconnection material 28a, 28b, 28c, etc. The disposition of the photovoltaic device 10 after step 56 is shown in FIGS. 11a and 11b. In the situation where the metallic interconnection material 28a, 28b, 28c, etc. is deposited over the entirety of the photovoltaic device's exposed surface, the edge 58a, 58b, 58c, etc. is created to prevent electrical connect between, for example, metallic interconnection material 28c and back contact layer 20c, since such contact would create a short circuit that would allow current flow to bypass photovoltaic cell 12c. The edge 58a, 58b, 58c, etc. may be created by acid etch, mechanical removal (abrasion), laser ablating, or any other desired method.

The described method for manufacturing 38 may be performed on an automated assembly line using known techniques. The isolation scribes and interconnection scribes may be cut or ablated using lasers. Multiple laser sources may be used in the method of manufacturing 38. Alternatively, light from a single laser source may be manipulated using known optics techniques in order to cut various scribes, either simultaneously or sequentially.

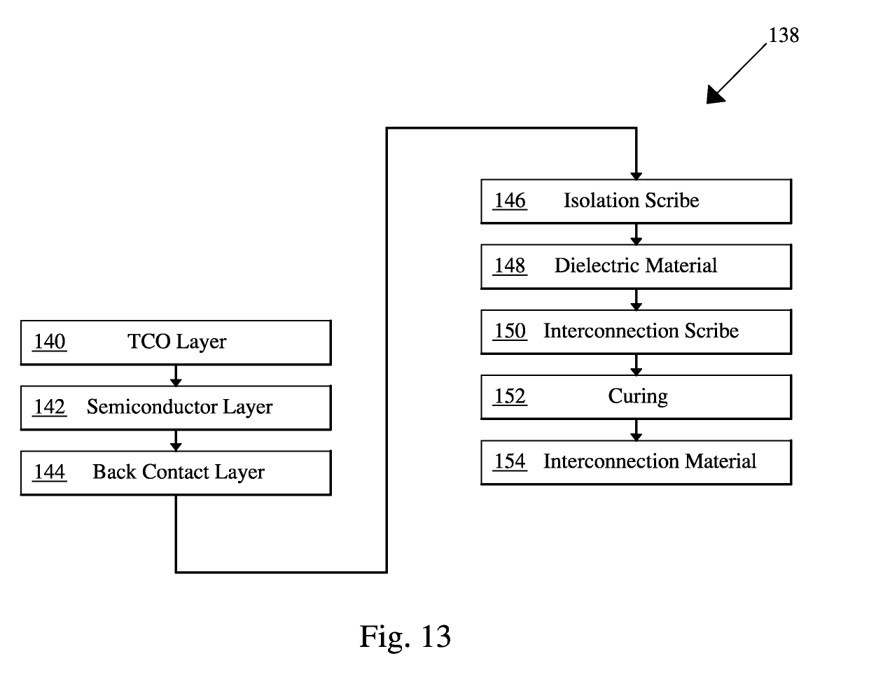

Referring now to FIG. 13, a flow chart of a method for manufacturing a photovoltaic device 110 according to another embodiment of the invention is shown generally at 138. The steps of the method shown in FIG. 13 are best understood in further reference to FIGS. 6a-11b and 14a and 14b.

Step 140 is the application of a transparent conductive oxide (TCO) layer 116 to the transparent substrate 114. Processes to apply the transparent conductive oxide layer 116 to the transparent substrate 114 are known in the art, and will not be detailed here. The transparent conductive oxide layer 116 is applied across the full surface of the transparent substrate 114. Step 142 is the application of a semiconductor layer 118. Processes to apply the semiconductor layer 118 are known in the art, and will not be detailed here. The semiconductor layer 118 is applied across the full surface of the transparent conductive oxide layer 116. Step 144 is the application of a back contact layer 120. Processes to apply the back contact layer 120 are known in the art, and will not be detailed here. The back contact layer 120 is applied across the full surface of the semiconductor layer 118. The back contact layer 120 may be sealed with, for example, chromium. At this point, the photovoltaic device 110 is in the condition similar to that shown in FIGS. 6a and 6b. It should be appreciated that the back contact layer 120, by covering the full surface of the semiconductor layer 118, provides protection against undesirable oxidation, contamination or deterioration of the semiconductor layer 118. As a result, the photovoltaic device may be brought through step 144, and then moved to a different facility where additional steps may be performed, without degradation of the materials of photovoltaic device.

At step 146 isolation scribes (not shown) are cut into the photovoltaic device 110. The disposition of the photovoltaic device 110 after step 146 is similar to that shown in FIGS. 7a and 7b. The isolation scribes are cut using a laser that ablates the transparent conductive oxide layer 116, the semiconductor layer 118, and the back contact layer 120 without affecting the transparent substrate 114.

Step 148 is the application of a dielectric material 126 to the back contact layer 120. The dielectric material 126 may be applied across the full surface of the back contact layer 120 or only a portion thereof, as desired. In each case, the dielectric material 126 substantially fills the isolation scribes formed in the step 146. The dielectric material 126 is a curable material, such as a UV curable polymer, for example. The dielectric material 126 may be applied is applied using an inkjet printing process, though any other desired process suitable to apply the dielectric material 126 may be used, such as a roll coating process, spraying application, and the like. During the step 148, the dielectric material 126 is applied in an uncured and flowable state.

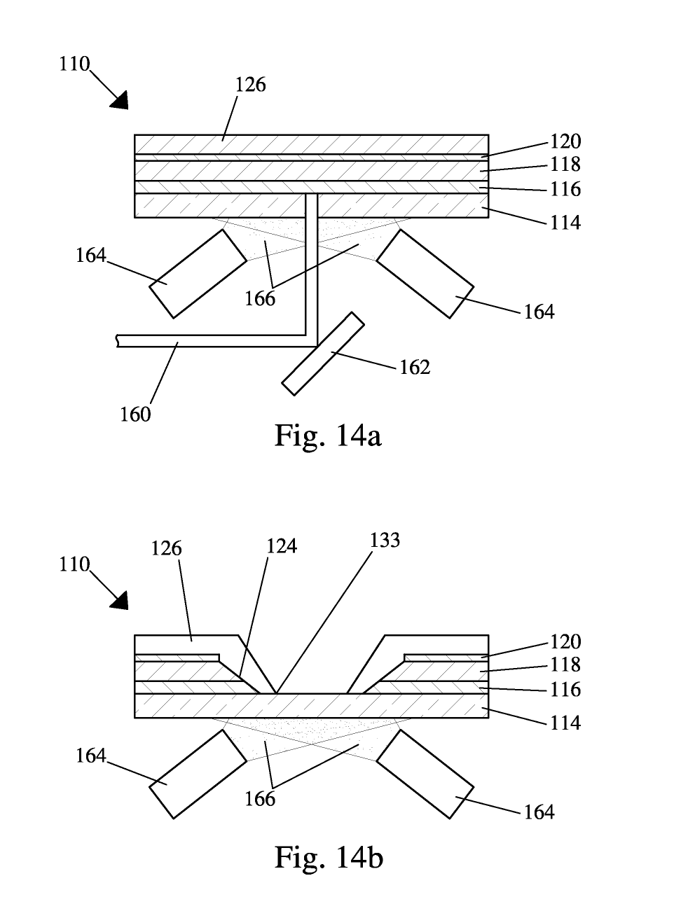

At step 150 at least one interconnection scribe 124 is cut into the photovoltaic device 110, as shown in FIG. 14a. The step 148 is performed by introducing a laser 160 to the substrate 114 of the device 110. The laser 160 may be applied directly to the device 110 or indirectly via a mirror 162. The laser passes through the transparent substrate 114 and the transparent TCO layer 116 and ablates the semiconductor layer 118 and the back contact layer 120 without affecting the transparent substrate 114 and the transparent conductive oxide layer 116 to form the interconnection scribe 124, as shown in FIG. 14b. The interconnection scribes 124 may comprise a series of discontinuous ablations of material between isolation scribes (similar to that shown in FIG. 8a), or alternatively, between an isolation scribe and an end edge of the photovoltaic device 110. The discontinuous ablations of the interconnection scribe 124 may result in a series of substantially circular dots or short rectilinear scribes (not shown) or the discontinuous ablation may result in a dashed line scribe, similar to that shown in FIG. 8a. Alternatively, the interconnection scribe 124 may comprise one continuous ablation of material to form a trough.

During the step 152, a curing means 164 is directed on the device 110 at the location of the laser ablation. It is understood that the curing means 164 may be directed on the device 110 at the location of the laser ablation during the step 150, as desired. The curing means 164 may be heat or UV light 166 or any means selected to cure the curable material of the dielectric material 126. As the laser 160 ablates one or more layers of material underneath the dielectric material 126, forces exerted by the plum of ablated material from the semiconductor layer 118 and/or the back contact layer 120 are forced through the uncured dielectric material 126, thereby opening a hole in the dielectric material 126. The surface tension in the uncured dielectric material 126 causes the uncured dielectric material 126 to flow into the hole ablated through the semiconductor layer 118 and the back contact layer 120. Being directed at the hole created by the laser 160, the curing means 164 causes the dielectric material 126 that has flowed therein to cure, thereby militating against the dielectric material 126 completely covering the TCO layer 116 exposed by the step 150, as shown in FIG. 14b. In this way, the step 150 the hole remains and a self-aligned gap (or via) 133 is formed that provides selective electrical communication with the TCO layer 116 while electrically insulating the sidewalls of the interconnection scribe 124 to militate against shunting. It is understood that changing any or all of the following may affect the sidewall profile of the dielectric material 126 and/or the width of the gap 133: the angle of the curing means 164; the intensity of the curing means 164; and a time delay between the laser ablation and the curing steps.

At step 154, a metallic interconnection material (not shown) is applied to the photovoltaic device 110. The disposition of the photovoltaic device 110 after step 152 is similar to that of the photovoltaic device 10 shown in FIGS. 11a and 11b. The metallic interconnection material is applied using an inkjet printing process, though any other desired process suitable to apply the material may be used. The metallic interconnection material may be deposited over the entirety of the exposed surface of the photovoltaic device 110, or alternatively may be selectively deposited within certain regions and not others. For example, similar to that shown in FIGS. 11a and 11b, the metallic interconnection material may be selectively deposited to overlap slightly onto the back contact layer 120 of a photovoltaic cell adjacent to another photovoltaic cell and continuously over the dielectric material 126 to the interconnection scribe 124.

The described method for manufacturing 138 may be performed on an automated assembly line using known techniques. The isolation scribes and interconnection scribes may be cut or ablated using lasers. Multiple laser sources may be used in the method of manufacturing 138. Alternatively, light from a single laser source may be manipulated using known optics techniques in order to cut various scribes, either simultaneously or sequentially.

From the foregoing description, one ordinarily skilled in the art can easily ascertain the essential characteristics of this invention and, without departing from the spirit and scope thereof, can make various changes and modifications to the invention to adapt it to various usages and conditions.

What is claimed is:

1. A photovoltaic device comprising:
a substrate having a transparent conductive oxide layer, a conductive back contact layer, and a semiconductor layer formed thereon;
an isolation scribe formed through the transparent conductive oxide layer, the conductive back contact layer, and the semiconductor layer to define a first photovoltaic cell and a second photovoltaic cell, the isolation scribe electrically isolating the first photovoltaic cell from the second photovoltaic cell; and
an interconnection scribe formed through the back contact layer and the semiconductor layer of the second photovoltaic cell, the interconnection scribe spaced laterally apart from the isolation scribe and facilitating a series connection between the first photovoltaic cell and the second photovoltaic cell.

2. The photovoltaic device of claim 1, wherein the interconnection scribe is formed near or at a center of the second photovoltaic cell.

3. The photovoltaic cell of claim 2, wherein the interconnection scribe is formed by a series of discontinuous ablations separated by non-scribed layers of the photovoltaic cell.

4. The photovoltaic device of claim 1, further comprising a metallic interconnection material providing electrical communication between the conductive back contact layer of the first photovoltaic cell and the transparent conductive oxide layer of the second photovoltaic cell exposed by the interconnection scribe.

5. The photovoltaic device of claim 4, wherein the metallic interconnection material is disposed on a dielectric material that fills the isolation scribe.

6. The photovoltaic device of claim 1, further comprising a dielectric material filling the isolation scribe.

7. A method for manufacturing a photovoltaic device comprising:
forming a plurality of isolation scribes in a photovoltaic device through a transparent conductive oxide layer, a semiconductor layer, and a back contact layer of disposed upon a substrate to define an array of photovoltaic cells on the photovoltaic device;
forming interconnection scribes through the semiconductor layer and the back contact layer of each of the photovoltaic cells to expose a portion of the transparent conductive oxide layer; and
depositing a dielectric material into the plurality of isolation scribes, wherein at least a portion of the dielectric material is disposed on at least a portion of the back contact layer of one of the photovoltaic cells, a portion of the back contact layer of a another of the photovoltaic cells adjacent to the one of the photovoltaic cells, and at least a portion of the interconnection scribe of the one of the photovoltaic cells.

8. The method of claim 7, wherein the deposited dielectric material has a first portion with a thickness and a second portion with a thickness less than the thickness of the first portion.

9. The method of claim 8, wherein the second portion of the dielectric material is deposited in the interconnection scribe.

10. The method of claim 9, wherein the dielectric material is deposited using an inkjet printing process.

11. The method of claim 7, wherein the dielectric material is deposited using an inkjet printing process to form vias providing communication with the transparent conductive oxide layer of the interconnection scribe.

12. The method of claim 7, wherein the dielectric material is formed from a curable material.

13. The method of claim 12, further comprising the step of partially curing the curable to material.

14. The method of claim 13, further comprising the step of removing a portion of the curable material that is disposed in the interconnection scribe to expose the transparent conductive oxide layer.

15. The method of claim 14, further comprising the step of fully curing the curable material.

16. The method of claim 12, wherein the curable material is deposited as a liquid.

17. The method of claim 16, wherein the interconnection scribe is formed by directing a laser at the photovoltaic device through the substrate to remove the semiconductor layer and the back contact layer and facilitating a flow of the dielectric material into the interconnection scribe.

18. The method of claim 17, further comprising the step of curing the dielectric material within the interconnection scribe to form vias in the interconnection scribe to provide communication with the transparent conductive oxide layer.

19. The method of claim 12, further comprising a step of depositing a metallic interconnection layer at least partially covering the dielectric material and in contact with the transparent conductive oxide of the one of the photovoltaic cells and the back contact layer of the another of the photovoltaic cells to provide a series electrical connection between the one of the photovoltaic cells and the another of the photovoltaic cells.

20. The method of claim 12, wherein the interconnection scribe is spaced laterally apart from the isolation scribe.
